(19) United States
(12) Patent Application Publication
(10) Pub. No.: US 2008/0144143 A1
(43) Pub. Date: Jun. 19, 2008

(54) Method for color characterization and related systems

(76) Inventors: Nickolai D. Solechnik, Ascot (GB); Raymond Dwight Iveson, Virginia Water (GB)

Correspondence Address: THE PROCTER & GAMBLE COMPANY;INTELLECTUAL PROPERTY DIVISION - WEST BLDG., WINTON HILL BUSINESS CENTER - BOX 412, 6250 CENTER HILL AVENUE, CINCINNATI, OH, 45224, US

(21) Appl. No.: 11/590,024

(22) Filed: Oct. 31, 2006

(51) Int. Cl. G03F 3/08

(52) U.S. Cl. 358/520

(57) ABSTRACT

A method of characterizing object color includes acquiring a color data set from a plurality of objects that may be treated with a personal care or beauty product or to which the personal care or beauty product may be applied, the color data set representing color measurements of the plurality of objects, and expressing the color data set in a three-dimensional color space. The color data set may be a hair color data set, for example. The method also includes transforming the color data set into a plane, and defining a region of the plane in which the transformed color data set is disposed and a space about the region as a first character color space. Where the color data is hair color data, the color space may be a natural hair color space, for example.

### FIELD OF THE INVENTION

The present disclosure generally relates to a method for color characterization, and in particular, a method for characterization of color produced by a personal care or beauty product, such as a hair color product, and a system that uses such a characterization.

### BACKGROUND OF THE INVENTION

Each year, consumers spend several billion dollars worldwide on hair color products. It has been determined that a consumer's choices relating to hair color products may be attributable to three main factors. First, despite the consumer's desire to color his or her hair, the consumer wants the hair to eventually return to its original color. Second, the consumer is looking for a straight-forward product requiring a limited amount of effort for preparation and application. Third, the consumer is concerned with obtaining “just the right” color.

As a consequence, a considerable amount of time and money has been spent attempting to understand each of the three factors. In particular, as to the third factor, a considerable amount of time and money has been spent attempting to understand consumer perceptions as to a shade or a palette of shades capable of being produced by a particular hair color product or family of such products. This information may be obtained from focused market testing. Alternatively, the information may be obtained through the use of broad-based surveys. Still, both market testing data and survey data may be influenced by the subjective judgment of the participant(s).

Accordingly, it would be desirable to provide a method that permits a more standardized, more objective characterization of hair color produced by hair color products. It would also be desirable to provide a system that then uses the color characterization. In a more general sense, it would be desirable to have a method for standardized characterization of color produced by personal care or beauty products, where the hair color produced by a hair color product is but one example, and a related system for use of the color characterization.

### SUMMARY OF THE INVENTION

In one aspect, a method of characterizing hair color includes acquiring a hair color data set from a plurality of hair samples with naturally-occurring color, the hair color data set representing color measurements of the plurality of hair samples, and expressing the hair color data set in a three-dimensional color space. The method also includes transforming the hair color data set into a plane, and defining a region of the plane in which the transformed hair color data set is disposed and a space about the region as a natural hair color space.

In another aspect, a method of characterizing object color includes acquiring a color data set from a plurality of objects that may be treated with a personal care or beauty product or to which the personal care or beauty product may be applied, the color data set representing color measurements of the plurality of objects, and expressing the color data set in a three-dimensional color space. The method also includes transforming the color data set into a plane, and defining a region of the plane in which the transformed color data set is disposed and a space about the region as a first character color space.

In a further aspect, an apparatus for characterizing hair color includes a spectrophotometer, an output device, and a computing device, the computing device coupled to the spectrophotometer and the output device. The computing device includes a processor and memory, the memory storing a natural hair color space, the color space comprising three dimensional hair color data that has been transformed into a plane. The computing device is programmed to receive a color measurement from the spectrophotometer, to compare the hair color measurement with the natural hair color space, and to provide an indication of the naturalness of the hair sample according to the comparison of the hair color measurement with the natural hair color space.

### BRIEF DESCRIPTION OF THE DRAWINGS

While the specification concludes with claims particularly pointing out and distinctly claiming the subject matter that is regarded as the present invention, it is believed that the invention will be more fully understood from the following description taken in conjunction with the accompanying drawings. Some of the figures may have been simplified by the omission of selected elements for the purpose of more clearly showing other elements. Such omissions of elements in some figures are not necessarily indicative of the presence or absence of particular elements in any of the exemplary embodiments, except as may be explicitly delineated in the corresponding written description. None of the drawings are necessarily to scale.

FIG. 1 is a flowchart of a method of characterizing hair color according to the present disclosure;

FIG. 2 is a three-dimensional graph of the color of hair samples plotted using L*, a*, and b*;

FIG. 3 is a two-dimensional graph of the color of the hair samples of FIG. 2 plotted using two variables or components, the variables or components being a function of L*, a* and b*;

FIG. 4 is a schematic diagram of a system according to the present disclosure that uses the hair color characterization; and

FIG. 5 is a flowchart of a method of characterizing color produced by a personal care or beauty product according to the present disclosure.

### DETAILED DESCRIPTION OF THE INVENTION

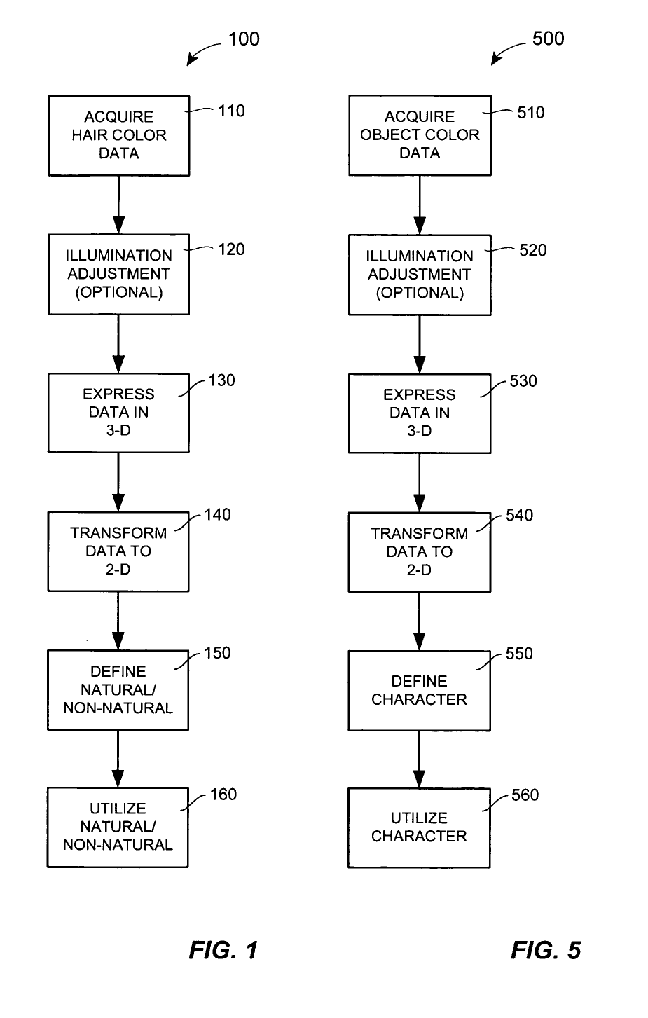

A method 100 of characterizing hair color produced by a hair color product is discussed first with reference to FIG. 1. As will be explained later with reference to FIG. 5, the method 100 is a particularized expression of a family of methods, each method within the family directed to a particular personal care or beauty product or a category of such products. Thus, while the method in FIG. 5 is directed to such products generally, the method 100 of FIG. 1 focuses on hair color products.

Further, the method 100 characterizes hair color in terms of natural or non-natural, or other, shades. Other characterizations could have been and may be pursued relative to the color produced by a hair color product. However, according to the embodiment of the method 100 illustrated in FIG. 1, the hair color is discussed in terms of natural and non- natural shades.

Thus, the method 100 begins at a first block 110, wherein data may be acquired. The data acquisition may produce a hair color data set from a plurality of hair samples, such as from single source ponytails. Because the desired characterization involves natural and non-natural shades, the initial data acquisition may be from ponytails of heads that have not been artificially colored, i.e., with naturally-occurring colors. It will be recognized that if the desired characterization relied upon other than natural vs. non- natural occurring color, the initial data acquisition could have been from ponytails of heads that had been artificially colored.

The data acquisition may be performed using a d₈ (integrating sphere) spectrophotometer, such as the 2600d- or 3600d-model spectrophotometer commercially available from Konica Minolta Sensing Americas, Inc. of Ramsey, N.J. The color data obtained using the spectrophotometer may be collected manually, that is by reading the color measurements from the spectrophotometer and then entering that data into a table or a list, whether the table or list exists in hard copy (such as in the form of a notebook) or electronic form (such as in the form of a spreadsheet or data element array). Alternatively, the data may be captured automatically by attaching the spectrophotometer to a computing device, and uploading the data to the computing device from the spectrophotometer over a data link or cable, such as an RS-232C cable.

According to an embodiment of the disclosure, the color data may be expressed in the form of L*a*b* coordinates. The L*a*b* color space (developed by the Commission International de l'Eclairage (CIE), and referred to as CIELAB) uses three numbers (L*, a*, b*), each of which corresponds to one of three coordinates, to describe a color. The L* number quantifies an object's lightness or darkness on a scale of zero to 100, with 0=black and 100=white. The a* number quantifies an object's redness or greenness. The a* number can be positive or negative, with positive numbers being red (the higher the number, the redder the object) and negative numbers being green (the higher the number, the greener the object). The a* number can also be zero, which is intermediate between red and green. The b* number quantifies an object's yellowness or blueness. Here as well, b* can be positive (yellow) or negative (blue), and the larger the number, the more intense the color.

It will be recognized, however, that the color data could have been expressed in another form for the purposes of this disclosure. For example, the XYZ color space or the L*C*H* color space (also developed by the CIE) may have been used in place of the CIELAB color space. Furthermore, CMC color tolerancing may be used instead of traditional CIELAB.

It will be further recognized that illumination is a factor in the expression of the color data into a given color space. That is, the data acquired at block 110 may be initially in the form of full reflectance spectra. This data may then be converted mathematically into, for example, the L*a*b* color space in accordance with the illumination source used, which is typically D65 illumination (sometimes referred to as “standard daylight”). According to certain embodiments, this may be satisfactory. Optionally, at block 120, the data acquired at block 110 may be mathematically converted into L*a*b* values for variable illumination conditions. For example, the L*a*b* values may be representative of illumination conditions typical of a hair salon, a bathroom, an office, etc. instead of standard daylight.

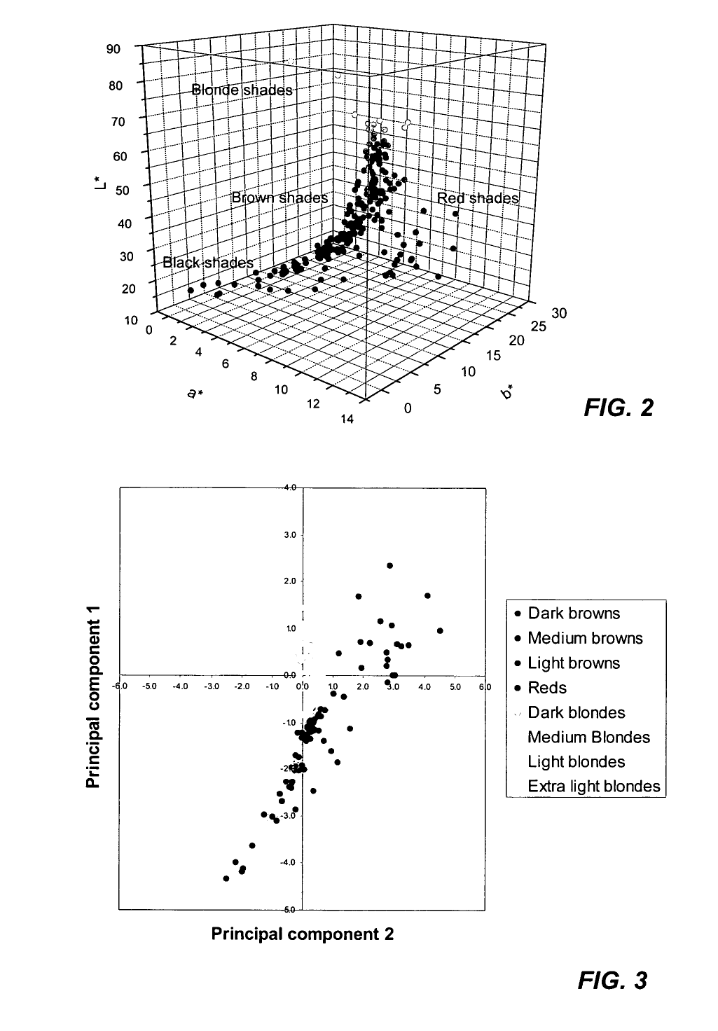

Thus, depending on the particular embodiment, either after the block 110 or 120, the method 100 may proceed to block 130. At block 130, the hair color data set may be expressed in three dimensions. According to the present disclosure, the data was expressed in the three dimensions of the CIELAB color space. FIG. 2 illustrates an exemplary three-dimensional plot of the colors occurring naturally in the samples tested (i.e., ponytails without artificial coloring). It will be recognized that the plot forms a boomerang-shape cloud in the CIELAB color space.

From observation of the data, it was determined that the data for naturally occurring hair color fits to a plane, with a R² factor of 96%. Moreover, the two principal components that define the plane account for 99.31% of the variation in the naturally occurring hair color data set. By transforming the hair color data set into two dimensions, it is believed that mathematical simplicity may be gained while losing less than 1% of precision.

It will be recognized that it is not a requirement of the method according to the present disclosure that the two principal components account for greater than 99% of the variation in the data set. In fact, it is believed that even if two principal components account for a smaller percentage of the overall data variation, expression of the data in terms of these two components may still achieve suitable simplicity. For example, if the principal component analysis of the data in three dimensions identifies two components that account for at least 85% of the data variation, the improvement in characterization, visualization, and analysis may still be significant. It may even be the case that two components that account for an even smaller percentage of the variation in the data may be provide acceptable improvements as to suggest presentation in two dimensions.

It will be also recognized that mathematical simplicity may produce resultant improvements in the amount of resources required (fewer resources required) and in the speed of computations (quicker computational times) over more complex systems. Additionally, mathematical simplicity may improve the ability to analyze the data, to visualize the data, and to otherwise interpret the data.

Thus, at block 140, the data initially expressed in three dimensions may be transformed using Eigen vectors derived from the principal component analysis into the plane discussed above, and may be plotted in two dimensions. This data set may be referred to as the transformed hair color data set. According to the present embodiment, the two-dimensional coordinates are linear combinations of the CIELAB coordinates, L*, a*, and b*. A plot of the transformed hair color data is shown in FIG. 3.

At a block 150, the determination may be made to define a region in which the transformed hair color data set is located as the “natural” hair color space. In this regard, it should be noted that the natural hair color space need not include, and according to this embodiment does not include, the entire plane defined by the principal components. Instead, the natural hair color space includes a region of that plane in which the transformed color data is disposed, as well as those points in the CIELAB color space about the region, for example, within one unit (according to the CIEDE2000 standard) of the region of the plane. According to the CIEDE2000 standard, a color difference of less than one is considered not to be noticeable by the human eye. The determination of the boundaries of the region on the plane may be made, for example, by selecting the four best polynomial fit lines through the transformed hair color data set.

In assessing how the natural hair color space may compare with consumer perception of natural-looking hair color, data was subsequently acquired from artificially colored hair samples, and that data was compared against the natural hair color space. The samples were colored using hair color products having shades determined by market testing to be the most natural-looking colors. It was determined that the majority of these shades had a CIEDE2000 color difference of less than one relative to the natural hair color space. It was thus determined that the natural hair color space was in accord with consumer perception of natural-looking hair color, as well as being representative of naturally occurring hair color.

Having thus defined the natural hair color space, many different uses may be made of the space, as represented by block 160. In general terms, these uses rely on a characterization of a hair color shade according to whether the hair color shade falls within the natural hair color space.

For example, if “natural” shades are important to a hair color product, the color palette of the product may be compared to the natural hair color space to determine the percentage of shades that fall within the space (and are therefore natural) and the percentage of shades that fall outside of the space (and are therefore non-natural or other). This may provide one basis on which to make determinations about the palette (e.g., that the palette has a significant number of shades that fall within the natural hair color space, and thus is very natural), or to compare one palette with another palette (e.g., which is more natural). It will be recognized that this same determination could be made about a single shade as well.

In fact, the location of a shade, or the locations of the shades of a palette, relative to the natural hair color space may be used to make still other determinations. According to one embodiment, the location of a shade within the natural hair color space, which may include several different colors as illustrated in FIG. 3, may be used to make a determination about the color of the shade (e.g., brown, or more brown than red). According to another embodiment, the distribution of the shades inside (and, potentially, outside) the natural color space may be used to make determinations about the palette (e.g., more naturally occurring browns than reds). According to still another embodiment, the uniformity of the shades within the space (e.g., clustering vs. broad distribution) may provide other bases on which to make determinations.

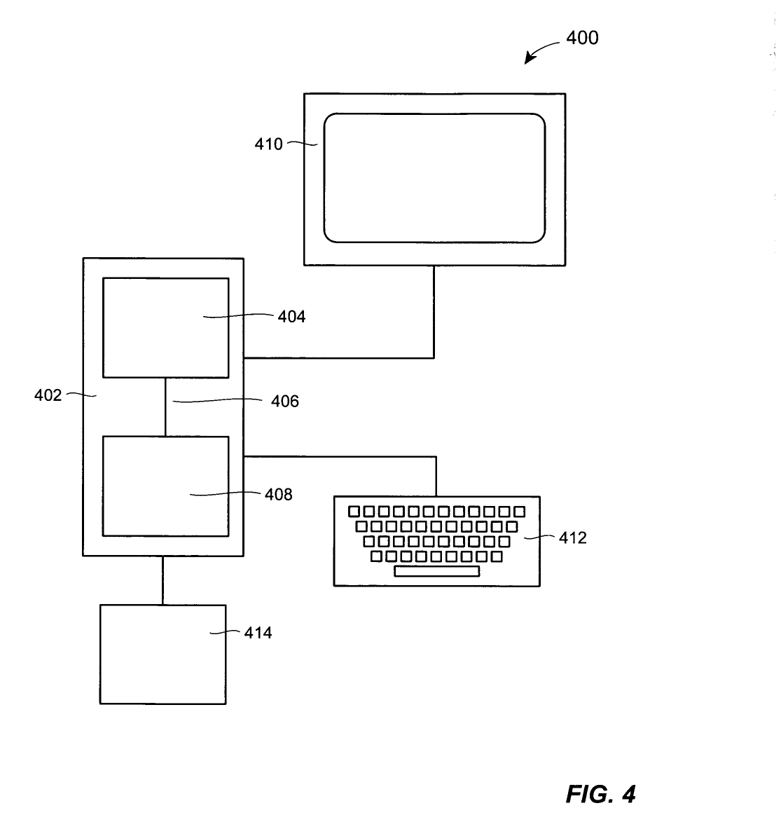

The speed at which the comparison may be made is greatly enhanced through the use of a the color space transformed into two-dimensions, although, as pointed out above, the collapsing of the dimensions may come with little loss in precision. In fact, the speed of the comparison may also permit real-time (or near real-time) analysis of hair color and selection of hair care products. That is, a hair sample from a prospective customer may be tested using the spectrophotometer mentioned above, to acquire a hair color measurement. The hair color measurement may be compared with the natural hair color space, to provide an indication of the “naturalness” of the customer's existing hair color, which comparison may be displayed visually to the consumer through the use of a video display unit or other graphic display device (whether electronic or hard copy). The hair color measurement may also be compared with hair color readings for a palette of a hair color product, and then compared for the best shade for the customers hair color needs. FIG. 4 illustrates a system 400 that may be used to perform such a comparison, which system may also be used in the method according to FIG. 1 as well.

In particular, the system 400 includes computing device 402, such as a computer. However, this is merely by way of illustration and not by way of limitation, for the computing device 402 may include a workstation, Linux machine, or any other computing device. In particular, the computing device may be a device dedicated to performing the hair color comparison, and having little or no functionality beyond performing the method as programmed.

The computing device 402 may include one or more processors 404, which may themselves include one or more logical and/or physical processors. The processor 404 may be operatively coupled, via a bus 406, for example, to a memory/data storage medium 408. The computing device 402 may also be coupled to an output device, such as a display unit 410 (such as a cathode ray tube (CRT), a liquid crystal display (LCD) or any other type of display unit), and an input device, such as a keyboard 412. The computing device 402 may also be coupled to a spectrophotometer 414, such as the 2600d- or 3600d-model spectrophotometer commercially available from Konica Minolta Sensing Americas, Inc. of Ramsey, N.J.

Although the processor 404 and the memory/data storage device 408 are illustrated as internal to the computing device 402, the devices need not be located in the same physical space or physically-proximate to each other. Moreover, the data storage device 408 may include a data storage medium interface (e.g., a magnetic disk drive, a compact disk (CD) drive or a digital versatile disk drive (DVD) and an associated data storage medium (e.g., a magnetic disk, a CD or a DVD). In fact, the data storage device 408 may be in the form of any machine-accessible medium.

A machine accessible medium includes any mechanism that provides (i.e., stores and/or transmits) information in a form accessible by a machine (e.g., a computer, workstation, Linux device, network device, any device with a set of one or more processors, etc.). For example, a machine accessible medium includes recordable/non-recordable magnetic, optical and solid-state media (e.g., read-only memory (ROM), programmable read-only memory (PROM), erasable programmable read-only memory (EPROM), electrically erasable programmable read-only memory (EEPROM), random access memory (RAM), magnetic disk storage media, optical storage media, flash memory devices, etc.), as well as electrical, optical, acoustical or other form of propagated signals (e.g., carrier waves, infrared signals, digital signals, etc).

As stated above, the system 400 could be used to carry out a method utilizing the hair color characterization. That is, the color of a hair sample may be acquired through the use of the spectrophotometer 414, and automatically entered into the computing device 402. The computing device 402 may have the natural hair color space already stored within the memory 408. The computing device 402 may compare the acquired color data with the natural hair color space to determine if the color data falls within the color space. The computing device may then provide a characterization of the color of the hair sample (natural or non-natural, for example) via the display device 410, for example, according to whether the color data falls within the color space.

As was mentioned at the outset, it will also be recognized that the method according to FIG. 1 may be a particular embodiment of a more general method for use with other products, such as other personal care and beauty products. FIG. 5 illustrates such a method 500. It will be recognized that the comments made above relative to the method 100 may also apply to the method 500. For example, to the extent that a transformation is made from three dimensions to two dimensions (a plane) in the method 500, as in the method 100, the components that define the plane may account for 99% of the variation in the data set, but the components may also account for a lesser percentage and still may fall within the scope of the present disclosure.

The method 500 begins at block 510, wherein the color data set is acquired from a plurality of objects treated with the product or to which the product has been applied, the color data set representing color measurements of the plurality of objects. Similar to the method 100 above, the method 500 includes a block 520, wherein the illumination may be optionally adjusted. According to blocks 530 and 540, the color data set may be expressed in the traditional three-dimensional CIELAB color space, and then transformed into two dimensions (a plane) according to a best-fit plane for the color data collected. At block 550, the two-dimensional plot may then be used to define a color space (e.g., a region of the plane in which the transformed color data set is disposed and a space about the region) for a characteristic or set of characteristics. At block 560, the color characterization may be used, for example, to characterize the shade of a object's color produced by a product as having either a first character or not having the first character according to whether the shade falls within the color space. Cosmetics are but one additional example of a product, in addition to hair color products, that may be characterized according to this method 500.

All documents cited in the Detailed Description are, in relevant part, incorporated herein by reference; the citation of any document is not to be construed as an admission that it is prior art with respect to the present invention.

While particular embodiments of the present invention have been illustrated and described, it would be obvious to those skilled in the art that various other changes and modifications can be made without departing from the spirit and scope of the invention. It is therefore intended to cover in the appended claims all such changes and modifications that are within the scope of this invention.

What is claimed is:

1. A method of characterizing hair color, the method comprising:
acquiring a hair color data set from a plurality of hair samples with naturally- occurring color, the hair color data set representing color measurements of the plurality of hair samples;
expressing the hair color data set in a three-dimensional color space;
transforming the hair color data set into a plane;
defining a region of the plane in which the transformed hair color data set is disposed and a space about the region as a natural hair color space.

2. The method according to claim 1, further comprising converting the hair color data set for variable illumination conditions prior to expressing the hair color data set.

3. The method according to claim 1, wherein the plane is defined by two components that account for greater than 85% of the variation in the hair color data set.

4. The method according to claim 3, wherein the plane is defined by two components that account for greater than 99% of the variation in the hair color data set.

5. The method according to claim 1, wherein the three-dimensional color space is the CIELAB color space.

6. The method according to claim 5, wherein the three-dimensional color space is defined by components L*, a*, b*, the plane is defined by a first component and a second component, and the first and second components are each linear combinations of L*, a*, b*.

7. The method according to claim 1, further comprising:
acquiring a hair color measurement for a hair sample;
comparing the hair color measurement with the natural hair color space; and
providing an indication of the naturalness of the hair sample according to the comparison of the hair color measurement with the natural hair color space.

8. The method according to claim 7, wherein the indication is visually displayed.

9. A method of characterizing object color, the method comprising:
acquiring a color data set from a plurality of objects that may be treated with a personal care or beauty product or to which the personal care or beauty product may be applied, the color data set representing color measurements of the plurality of objects;
expressing the color data set in a three-dimensional color space;
transforming the color data set into a plane; and
defining a region of the plane in which the transformed color data set is disposed and a space about the region as a first character color space.

10. The method according to claim 9, further comprising converting the color data set for variable illumination conditions prior to expressing the color data set.

11. The method according to claim 9, wherein the plane is defined by two components that account for greater than 85% of the variation in the color data set.

12. The method according to claim 11, wherein the plane is defined by two components that account for greater than 99% of the variation in the color data set.

13. The method according to claim 9, wherein the three-dimensional color space is the CIELAB color space.

14. The method according to claim 13, wherein the three-dimensional color space is defined by components L*, a*, b*, the plane is defined by a first component and a second component, and the first and second components are each linear combinations of L*, a*, b*.

15. An apparatus for characterizing hair color, the apparatus comprising:
a spectrophotometer;
an output device; and
a computing device,
the computing device coupled to the spectrophotometer and the output device,
the computing device comprising a processor and memory,
the memory storing a natural hair color space, the color space comprising three dimensional hair color data that has been transformed into a plane,
the computing device programmed to receive a color measurement from the spectrophotometer,
the computing device programmed to compare the hair color measurement with the natural hair color space, and
the computing device programmed to provide an indication of the naturalness of the hair sample according to the comparison of the hair color measurement with the natural hair color space.

16. The apparatus according to claim 15, wherein the output device is a video display device.
